(19) United States
(12) Patent Application Publication
(10) Pub. No.: US 2012/0031651 A1
(43) Pub. Date: Feb. 9, 2012

(54) CIRCUIT BOARD

(75) Inventors: TZYY-JANG TSENG, Hsinchu City (TW); Chang-Ming Lee, Taoyuan County (TW); Wen-Fang Liu, Taoyuan County (TW); Cheng-Po Yu, Taoyuan County (TW)

(73) Assignee: UNIMICRON TECHNOLOGY CORP., Taoyuan (TW)

(21) Appl. No.: 12/944,275

(22) Filed: Nov. 11, 2010

(30) Foreign Application Priority Data
Aug. 5, 2010 (TW) 099215014

(51) Int. Cl. H05K 1/02; H05K 1/18

(52) U.S. Cl. 174/252

(57) ABSTRACT

A circuit board including a circuit layer, a thermally conductive substrate, an insulation layer, and at least one thermally conductive material is provided. The thermally conductive substrate has a plane. The insulation layer is disposed between the circuit layer and the plane and partially covers the plane. The thermally conductive material covers the plane without covered by the insulation layer and is in contact with the thermally conductive substrate. The insulation layer exposes the thermally conductive material.

### CROSS-REFERENCE TO RELATED APPLICATION

This application claims the benefit of Taiwan Patent Application No. 099215014, filed on Aug. 5, 2010, which is hereby incorporated by reference for all purposes as if fully set forth herein.

### BACKGROUND OF THE INVENTION

1. Field of Invention

The present invention relates to a circuit board, and more particularly, to a circuit board that can accelerate the thermal energy transfer rate.

2. Related Art

The current electronic devices, such as mobile phones and computers, and the household appliances, such as televisions and refrigerators, include a plurality of electronic components, for example, active components or passive components. Most of the electronic components are mounted on a circuit substrate, and the electronic components output and receive electrical signals by using the circuitry of the circuit substrate. Thus, the electrical signals can be transmitted among the electronic components.

However, the electronic components will generate some thermal energy during the operation, and some electronic components, such as light-emitting diodes (LEDs) and power components, even generate a large amount of thermal energy during the operation. Therefore, how to accelerate the thermal energy transfer rate of the electronic components is a subject worth studying.

### SUMMARY OF THE INVENTION

The present invention is directed to a circuit board enabling to accelerate the thermal energy transfer rate of electronic components.

The present invention provides a circuit board including a circuit layer, a thermally conductive substrate, an insulation layer, and at least one thermally conductive material. The thermally conductive substrate has a plane. The insulation layer is disposed between the circuit layer and the plane, and partially covers the plane. The thermally conductive material covers the plane without covered by the insulation layer and is in contact with the thermally conductive substrate. The insulation layer exposes the thermally conductive material.

Based on the above, since the thermally conductive material covers the plane without covered by the insulation layer and is in contact with the thermally conductive substrate, the thermally conductive material and the thermally conductive substrate enable to accelerate the thermal energy transfer rate when operating electronic components generate thermal energy.

To make the features and advantages of the present invention more clear and understandable, the present invention will be described below in great detail through the embodiments in combination with the accompanying drawings.

### BRIEF DESCRIPTION OF THE DRAWINGS

The present invention will become more fully understood from the detailed description given herein below for illustration only, and thus are not limitative of the present invention, and wherein:

FIG. 1 is a cross-sectional schematic view of a circuit board according to an embodiment of the present invention; and

FIG. 2 is a cross-sectional schematic view of a circuit board according to another embodiment of the present invention.

### DETAILED DESCRIPTION OF THE INVENTION

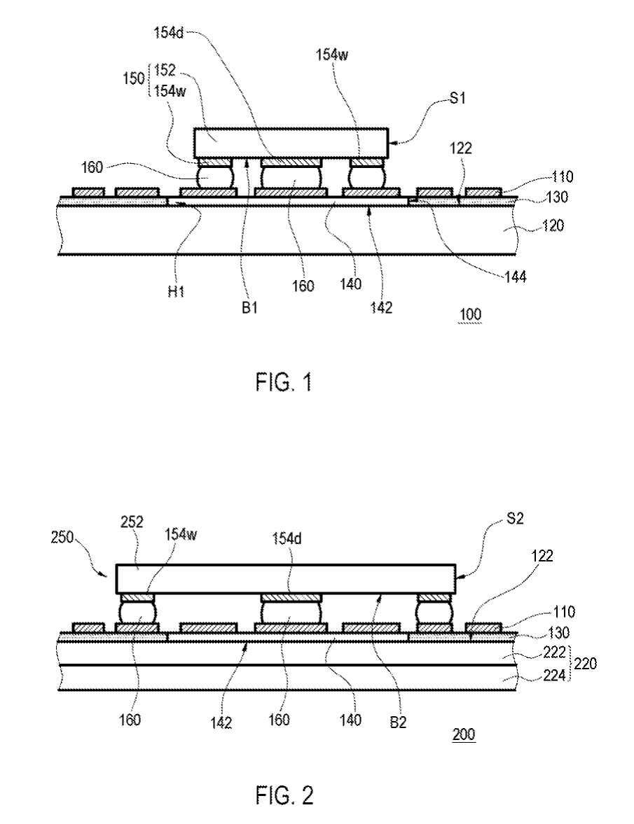

FIG. 1 is a cross-sectional schematic view of a circuit board according to an embodiment of the present invention. Referring to FIG. 1, a circuit board 100 includes a circuit layer 110, a thermally conductive substrate 120, an insulation layer 130, and a thermally conductive material 140. The thermally conductive substrate 120 has a plane 122, and both the insulation layer 130 and the thermally conductive material 140 are disposed between the circuit layer 110 and the plane 122.

The insulation layer 130 partially covers the plane 122, that is, the insulation layer 130 does not completely cover the plane 122. In other words, a part of the plane 122 is not covered by the insulation layer 130. The thermally conductive material 140 covers the plane 122 without covered by the insulation layer 130, and the insulation layer 130 exposes the thermally conductive material 140. The thermally conductive material 140 is in contact with the thermally conductive substrate 120, thereby thermally coupled to the thermally conductive substrate 120. Therefore, thermal energy can be transferred between the thermally conductive material 140 and the thermally conductive substrate 120 in the manner of thermal conduction.

The thermally conductive substrate 120 has a high thermal conductivity, for example, higher than 1 W/MK. The thermally conductive substrate 120 may be a metal plate or a carbon-material plate. The carbon-material plate generally refers to a plate made of carbon, such as a carbon fiber plate or a graphite plate. The metal plate may be an alloy plate, such as an aluminum magnesium alloy plate, or a plate substantially made of a single kind of metal, such as, aluminum plate or copper plate.

The thermally conductive material 140 may be an insulator and may be a ceramic layer, thermal pad, or thermal glue layer, in which the thermal pad is a solid. The thermal glue layer generally refers to a film layer formed of an adhesive having a high thermal conductivity, such as a thermal adhesive, in which the thermal adhesive may be in liquid state or colloidal state. In addition, both the thermal pad and the thermal adhesive may include a plurality of particles having high thermal conductivity, such as a metal particle, carbon powder, or silicon carbide (SiC) powder.

Although FIG. 1 only shows one thermally conductive material 140, the circuit board 100 may include a plurality of thermally conductive materials 140 in other embodiments. In other words, the number of the conductive materials 140 included by the circuit board 100 is one or more. Therefore, the number of the thermally conductive material 140 shown in FIG. 1 is only for an example and does not limit the present invention.

The thermal conductivity of the insulation layer 130 is lower than that of the thermally conductive substrate 120, and may be lower than 1 W/MK. For example, the thermal conductivity of the insulation layer 130 may be between 0.3 W/MK and 0.5 W/MK. In addition, the insulation layer 130 and the thermally conductive substrate 120 may be formed in the manner of lamination or printing.

When the insulation layer 130 and the thermally conductive substrate 120 are formed in the manner of lamination, the insulation layer 130 may be a prepreg, and the thermally conductive substrate 120 may be a thermal pad, that is, both the insulation layer 130 and the thermally conductive substrate 120 may be formed by laminating the prepreg and the thermal pad. In addition, before laminating the prepreg, the prepreg may be punched, routed, or laser ablated, so as to form an opening H1 in the insulation layer 130 and to enable the thermal pad to be disposed inside the opening H1.

When the insulation layer 130 and the thermally conductive substrate 120 are formed in the manner of printing, the thermally conductive material 140 may be a ceramic layer or thermal glue layer, and both the insulation layer 130 and the thermally conductive substrate 120 may be formed by applying a coating in liquid state, colloidal state, or is paste-like. For example, the coating may be resin or a coating containing resin. In addition, when the insulation layer 130 and the thermally conductive substrate 120 are formed in the manner of printing, after the coating is applied, the coating may be baked or illuminated by light, thereby curing the coating, in which the light may be ultraviolet light.

The circuit board 100 may further include an electronic component 150, such as a light-emitting diode, power component, chip package, or die. The electronic component 150 includes a component main body 152 and a plurality of pads 154d and 154w. The component main body 152 has a bottom surface B1, and the pads 154d and 154w are disposed on the bottom surface B1. The pad 154d may be a dummy pad, and the pad 154w may be a working pad. Thus, when the electronic component 150 is in operation, a current can only pass through the pad 154w without passing through the pad 154d.

It should be noted that, although FIG. 1 shows only one electronic component 150, the circuit board 100 may include a plurality of electronic components 150 in other embodiments. That is, the number of the electronic component 150 included by the circuit board 100 may be one or more. Therefore, the number of the electronic component 150 shown in FIG. 1 is only for an example and does not limit the present invention.

The electronic component 150 may be electrically connected to the circuit layer 110 in a manner of flip chip, as shown in FIG. 1. Particularly, the circuit board 100 may further include a plurality of solder bumps 160 connecting to the electronic component 150 and the thermally conductive substrate 120. Each solder bump 160 is connected to one of the pads 154w or 154d, and the solder bumps 160 are in contact with the pads 154w, 154d and the circuit layer 110. Therefore, the pads 154w and 154d may be electrically connected to the circuit layer 110 through the solder bumps 160, and may further be thermally coupled to the thermally conductive material 140 through the solder bumps 160 and the circuit layer 110.

In the embodiment in FIG. 1, the pads 154w and 154d are thermally coupled to the thermally conductive material 140 through the solder bumps 160 and the circuit layer 110. However, in other embodiments, when the pad 154d is a dummy pad, the pad 154d may be thermally coupled to the thermally conductive material 140 through the solder bumps 160 without through the circuit layer 110. Even the pad 154d may be in direct contact with the thermally conductive material 140 and may not need the solder bumps 160 to thermally coupled to the thermally conductive material 140. Therefore, even if the solder bumps 160 do not exist, the pad 154d also may be directly thermally coupled to the thermally conductive material 140.

Based on the above, since the pads 154w and 154d are thermally coupled to the thermally conductive material 140, and the thermally conductive material 140 is thermally coupled to the thermally conductive substrate 120, the thermally conductive material 140 and the thermally conductive substrate 120 can accelerate the thermal energy transfer rate when the operating electronic component 150 generates thermal energy, so as to reduce a probability that the electronic component 150 is overheating.

In addition, the thermally conductive material 140 covers the plane 122 without covered by the insulation layer 130 and is exposed by the insulation layer 130, so that the thermally conductive material 140 does not completely cover the plane 122 of the thermally conductive substrate 120, thereby capable of limiting the use of the thermally conductive material 140 of the circuit board 100. Moreover, the material cost of the thermally conductive material 140 is usually higher than that of the insulation layer 130, so that the overall manufacturing cost of the circuit board 100 in this embodiment can be reduced because the use of the thermally conductive material 140 can be limited.

It should be noted that, in addition to the manner of flip chip, the electronic component 150 also may be electrically connected to the circuit layer 110 in other manners, For example, the electronic component 150 may be electrically connected to the circuit layer 110 in the manner of wire bonding. Therefore, the manner of electrical connection between the electronic component 150 and the circuit layer 110 shown in FIG. 1 is only for an example and does not limit the present invention.

In addition, the component main body 152 further has a side surface Si connecting to the bottom surface B1. The thermally conductive material 140 has a contact surface 142 in contact with the thermally conductive substrate 120 and a side edge 144 connecting to the contact surface 142. The area of the bottom surface B1 may be smaller than that of the plane 122 covered by the thermally conductive material 140, that is, the area of the bottom surface B1 is smaller than that of the contact surface 142.

Further, in this embodiment, the thermally conductive material 140 may protrude from the side surface S 1, and the component main body 152 may not protrude from the side edge 144, so that the component main body 152 may be completely located inside the contact surface 142. Therefore, most of the thermal energy from the electronic component 150 is transferred by the thermally conductive material 140, so as to reduce a probability that the electronic component 150 is overheating.

FIG. 2 is a cross-sectional schematic view of a circuit board according to another embodiment of the present invention. Referring to FIG. 2, a circuit board 200 in this embodiment is similar to the circuit board 100 in the above embodiment. For example, circuit board 100, 200 both include some identical components. The difference between the circuit board 100, 200 only refers to a thermally conductive substrate 220 and an electronic component 250 included by the circuit board 200.

Particularly, the thermally conductive substrate 220 has a multiple-layer structure, and a component main body 252 included by the electronic component 250 has a bottom surface B2 and a side surface S2 connecting to the bottom surface B2. The area of the bottom surface B2 is larger than that of the plane 122 covered by the thermally conductive material 140. That is, the area of the bottom surface B2 is larger than that of the contact surface 142. In addition, the thermally conductive material 140 does not protrude from the side surface S2 of the component main body 252.

The thermally conductive substrate 220 has a multiple-layer structure and includes a thermally conductive layer 222 and a main body layer 224, and the thermally conductive layer 222 is located between the main body layer 224 and the insulation layer 130. The thermally conductive layer 222 has a high thermal conductivity, for example, higher than 1 W/MK. The thermally conductive layer 222 may be a metal layer or carbon-material layer.

The carbon-material layer generally refers to a film layer mainly formed by carbon, such as a carbon fiber layer, a graphite layer, or a diamond film. Therefore, the thermally conductive substrate 220 also can accelerate the thermal energy transfer rate, so as to reduce a probability that the electronic component 250 is overheating.

It should be noted that, the electronic component 250 further includes a plurality of pads 154d and 154w, and only one pad 154d is thermally coupled to the thermally conductive material 140, as shown in FIG. 2. However, both the pads 154w and 154d also can be thermally coupled to the thermally conductive material 140. In addition, in the circuit board 200 shown in FIG. 2, the thermally conductive substrate 220 may be replaced with the thermally conductive substrate 120 in FIG. 1. Therefore, the pads 154d, 154w and the thermally conductive substrate 220 shown in FIG. 2 are only for an example and do not limit the present invention.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A circuit board, comprising:
a circuit layer;
a thermally conductive substrate, having a plane;
an insulation layer, disposed between the circuit layer and the plane, wherein the insulation layer partially covers the plane; and
at least one thermally conductive material, covering the plane without covered by the insulation layer, and in contact with the thermally conductive substrate, wherein the insulation layer exposes the thermally conductive material.

2. The circuit board according to claim 1, wherein the thermally conductive substrate comprises a thermally conductive layer and a main body layer, and the thermally conductive layer is located between the main body layer and the insulation layer.

3. The circuit board according to claim 2, wherein the thermally conductive layer is a metal layer or a carbon-material layer.

4. The circuit board according to claim 1, wherein the thermally conductive substrate is a metal plate or a carbon-material plate.

5. The circuit board according to claim 1, wherein the thermally conductive material is a ceramic layer, a thermal pad, or a thermal glue layer.

6. The circuit board according to claim 1, further comprising at least one electronic component, wherein the electronic component comprises:
a component main body, having a bottom surface; and
a plurality of pads, disposed on the bottom surface and electrically connected to the circuit layer, wherein at least one pad is thermally coupled to the thermally conductive material.

7. The circuit board according to claim 6, further comprising a plurality of solder bumps connecting to the electronic component and the thermally conductive substrate, wherein each of the solder bumps is connected to one of the pads, and the solder bumps are in contact with the pads and the circuit layer.

8. The circuit board according to claim 6, wherein an area of the bottom surface is smaller than an area of the plane covered by the thermally conductive material.

9. The circuit board according to claim 8, wherein the thermally conductive material has a contact surface in contact with the thermally conductive substrate and a side edge connecting to the contact surface, and the component main body does not protrude from the side edge.

10. The circuit board according to claim 6, wherein an area of the bottom surface is larger than an area of the plane covered by the thermally conductive material.

11. The circuit board according to claim 10, wherein the component main body further has a side surface connecting to the bottom surface, and the thermally conductive material does not protrude from the side surface.
